(19) United States
(12) Patent Application Publication
(10) Pub. No.: US 2021/0059081 A1
(43) Pub. Date: Feb. 25, 2021

(54) SYSTEM AND METHOD FOR POWER MANAGEMENT FOR AN ISOLATED HOUSING

(71) Applicant: Dell Products L.P., Hopkinton, MA (US)

(72) Inventors: Steven Embleton, Austin, TX (US); Ben John Sy, Austin, TX (US); James Don Curlee, Round Rock, TX (US); Eric Michael Tunks, Austin, TX (US); Joshua S. Keup, Austin, TX (US)

(21) Appl. No.: 16/547,491

(22) Filed: Aug. 21, 2019

(51) Int. Cl. H05K 9/00; H05K 7/14

(52) U.S. Cl. CPC H05K 9/0009; H05K 7/1491; H05K 7/1489; H05K 9/0088

(57) ABSTRACT

A housing device for isolating electromagnetic interference emitting (EMI) devices includes an EMI isolating enclosure and a power manager. The power manager includes a filter mounted to a first portion of the EMI isolating enclosure. The power manager further includes a path, through the EMI isolating enclosure, that is isolated from an interior of the EMI isolating enclosure. The power manager further includes a power provider adapted to provide power to the filter by obtaining the power using the path.

### BACKGROUND

Multiple computing devices may be integrated into a predetermined area. For example, multiple computing devices may be included in a data center to provide the data center with more computational resources for performing one or more functionalities. When integrated into a predetermined area, the multiple computing devices may be close to one another.

### SUMMARY

In one aspect, a housing device for isolating electromagnetic interference emitting (EMI) devices in accordance with one or more embodiments of the invention includes an EMI isolating enclosure and a power manager. The power manager includes a filter mounted to a first portion of the EMI isolating enclosure; a path, through the EMI isolating enclosure, that is isolated from an interior of the EMI isolating enclosure; and a power provider adapted to provide power to the filter by obtaining the power using the path.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1.1 shows a diagram of a system in accordance with one or more embodiments of the invention.

FIG. 1.2 shows a diagram of the example system of FIG. 1.1 in a second configuration in accordance with one or more embodiments of the invention.

FIG. 1.3 shows a diagram of the example system of FIG. 1.2 in a third configuration in accordance with one or more embodiments of the invention.

FIG. 1.4 shows a diagram of the example system of FIG. 1.3 in a fourth configuration in accordance with one or more embodiments of the invention.

FIG. 2.1 shows a diagram of a frame in accordance with one or more embodiments of the invention.

FIG. 2.2 shows a second diagram of the frame in accordance with one or more embodiments of the invention.

FIG. 3.1 shows a diagram of a portion of an electromagnetic interference isolating enclosure in accordance with one or more embodiments of the invention.

FIG. 3.2 shows a diagram of a joint in accordance with one or more embodiments of the invention.

FIG. 3.3 shows a diagram of multiple portions of an electromagnetic interference isolating enclosure in accordance with one or more embodiments of the invention.

FIG. 4.1 shows a first diagram of a power manager in accordance with one or more embodiments of the invention.

FIG. 4.2 shows a second diagram of a power manager in accordance with one or more embodiments of the invention.

FIG. 4.3 shows a system including three housing devices in accordance with one or more embodiments of the invention.

FIG. 5 shows a diagram of a computing device in accordance with one or more embodiments of the invention.

### DETAILED DESCRIPTION

Specific embodiments will now be described with reference to the accompanying figures. In the following description, numerous details are set forth as examples of the invention. It will be understood by those skilled in the art that one or more embodiments of the present invention may be practiced without these specific details and that numerous variations or modifications may be possible without departing from the scope of the invention. Certain details known to those of ordinary skill in the art are omitted to avoid obscuring the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

In general, embodiments of the invention relate to systems, devices, and methods for managing Electromagnetic Interference (EMI). Devices may generate EMI as part of their operation. In a computing environment, EMI may negatively impact the operation of different devices within the environment.

A system in accordance with one or more embodiments of the invention may provide rack level EMI isolation for emitting devices. The system may include a non-structural EMI isolating enclosure attached to a structural frame. The non-structural EMI isolating enclosure may be adapted to provide EMI management services to devices disposed within the EMI isolating enclosure. The frame may provide structure management services to the EMI isolating enclosure and/or other devices disposed within the EMI isolating enclosure. Structure management services may include, for example, positioning devices, orienting devices, and/or receiving stress/forces from the EMI isolating enclosure and/or other devices to prevent the EMI isolating enclosure and/or the other devices from repositioning, reorienting, deforming, or otherwise changes in response to stress/forces being applied.

By including a non-structural EMI isolating enclosure, a system in accordance with embodiments of the invention may be of lower weight when compared to contemporary systems, be capable of more efficient transportation, and/or may be compatible with high density computing environment by providing high accuracy mechanical interconnectivity via the frame while providing EMI isolation services.

A system in accordance with one or more embodiments of the invention may also provide power management services to EMI isolated devices. To do so, the system may obtain power from a source, traverse the obtained power through a boundary of the EMI isolating enclosure while the devices disposed in the EMI isolating enclosure are isolated, and distribute the power to the EMI isolated devices. To do so, the system may include one or more integrated housings that are not adapted to be relocated. To obtain power, the system may include a power obtainer and a path through the EMI isolating enclosure that is isolated from an interior volume of the EMI isolating enclosure. By utilizing the path to obtain power, power may be provided to the integrated housings without relocating the integrated housings. Doing so may enable housing devices in accordance with embodiments of the invention to be dynamically reconfigured to meet the requirements of an environment (e.g., a high density computing environment) in which the housing devices will operate.

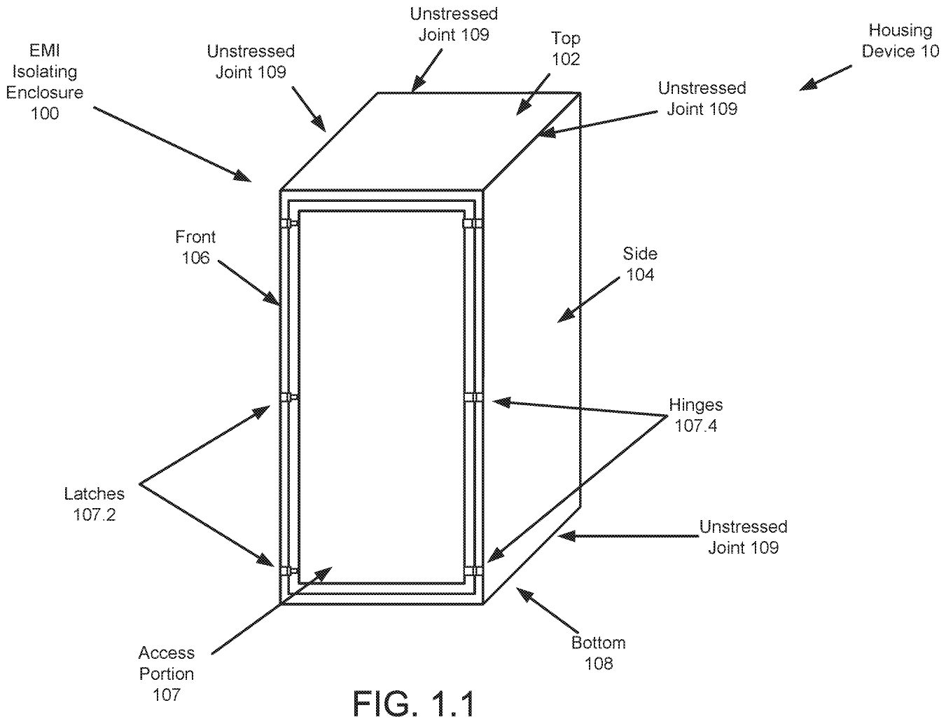

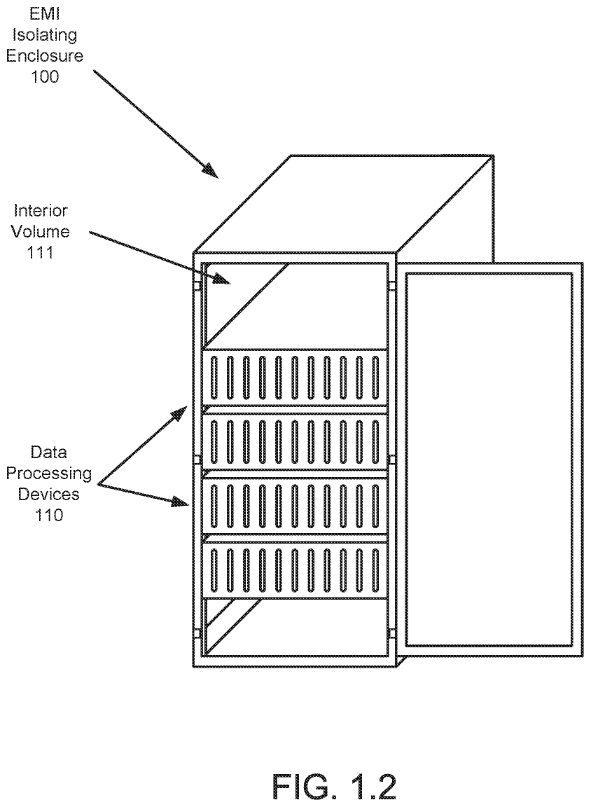

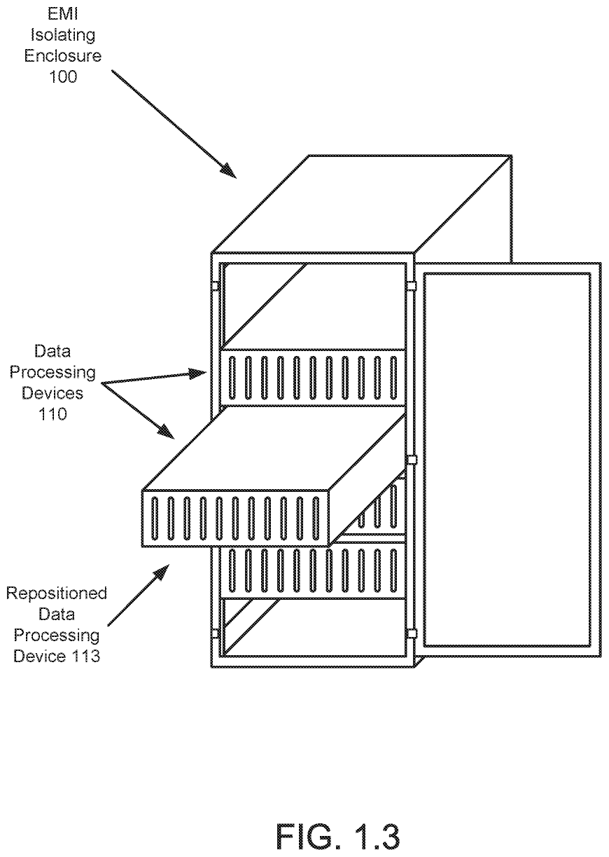

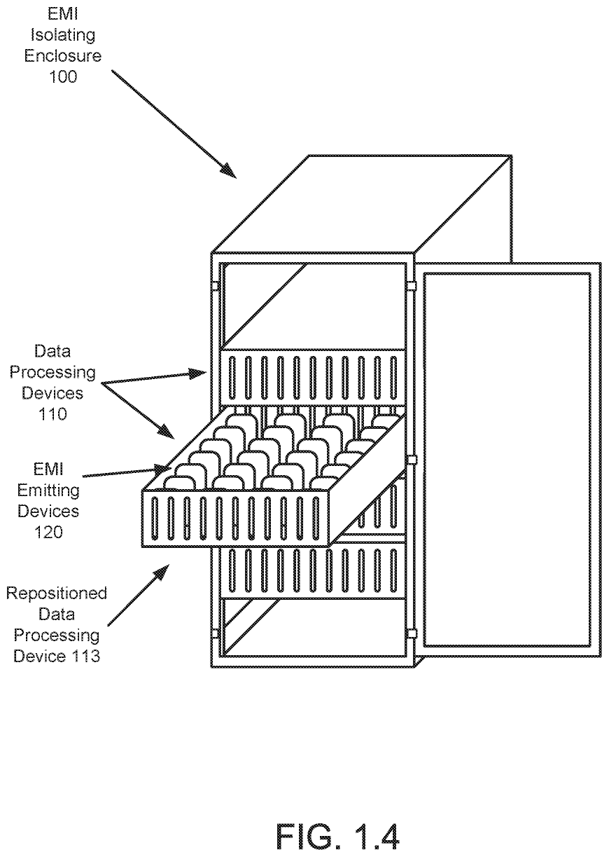

FIG. 1.1 shows an example system, e.g., a housing device (10), in accordance with one or more embodiments of the invention. The system may include an electromagnetic interference (EMI) isolating enclosure (100). The EMI isolating enclosure (100) may be a device for electromagnetically isolating devices disposed within the EMI isolating enclosure (100) from an ambient environment around the EMI isolating enclosure (100).

For example, one or more electromagnetic interference emitting devices may be disposed within the EMI isolating enclosure 100. The system illustrated in FIG. 1.1 may manage the electromagnetic interference generated by the one or more electromagnetic interference emitting devices by (i) limiting the space in which electromagnetic interference is allowed to freely propagate and/or (ii) attenuating the electromagnetic interference as it propagates out of the limited space. The limited space may be, for example, an interior of the EMI isolating enclosure (100).

To do so, the system of FIG. 1.1 may reduce the strength of the electromagnetic interference (i.e., electromagnetic radiation) when propagating from inside the EMI isolating enclosure (100) to an ambient environment around the EMI isolating enclosure (100) and/or other locations by at least 90 decibels or another suitable level of isolation. The electromagnetic interference isolation provided by the EMI isolating enclosure (100) may have a frequency dependent response. For example, the EMI isolating enclosure (100) may provide at least 90 decibels, or another suitable level of isolation, across a frequency band in which devices that may be disposed within the EMI isolating enclosure (100) are adapted to emit electromagnetic interference, In other frequency bands, the EMI isolating enclosure (100) may provide different levels or no electromagnetic interference isolation for devices disposed within the EMI isolating enclosure (100).

Accordingly, an EMI isolating enclosure (100) in accordance with one or more embodiments of the invention may provide electromagnetic interference suppression and/or isolation services that are frequency dependent. In one or more embodiments of the invention, an EMI isolating enclosure (100) provides electromagnetic interference isolation by reducing the strength of electromagnetic interference across at least one frequency band by a predetermined amount (e.g., 90 decibels, 75 decibels, 60 decibels, 30 decibels, etc.). The frequency band may be associated with the devices that generate the electromagnetic interference.

An EMI emitting device may be any type of hardware device that intentionally emits electromagnetic radiation as part of its operation. The emissions of electromagnetic radiation may be, for example, continuous, periodic, or intermittent (e.g., at any point in time based on the operation of the respective EMI emitting device). An EMI emitting device may be, for example, a personal electronic device such as a cellular device (e.g., smart phone, cell phone, etc.), a personal computer (e.g., any type of computing device with wireless communications capabilities such as a tablet computer, a laptop computer, etc.), a watch (e.g., a wireless smart watch), or any other type of hardware device that intentionally emits electromagnetic radiation for any purpose (e.g., communications, detection, etc.).

The electromagnetic interference emitted by an electromagnetic interference emitting device may be frequency dependent. That is, the electromagnetic interference emitted by the electromagnetic interference emitting device may be stronger in a first frequency band and weaker in a second frequency band (or may have different frequency dependencies). To provide electromagnetic interference suppression services, a EMI isolating enclosure (100) in accordance with one or more embodiments of the invention may attenuate the electromagnetic interference emitted by an electromagnetic interference emitting device by at least a predetermined amount (e.g., 90 decibels or another suitable level) across at least one frequency band in which the electromagnetic interference emitting device emits electromagnetic interference. The at least one frequency band may be, for example, the frequency band in which the emitted electromagnetic interference has a largest magnitude.

In one or more embodiments of the invention, an electromagnetic interference emitting device emits electromagnetic interference having frequency content between 700 megahertz and 10 gigahertz. An electromagnetic interference emitting device may emit electromagnetic interference having different frequency content without departing from the invention.

The housing device (10) may also provide power management services. To provide power management services, the housing device (10) may obtain power from a source that is external to the EMI isolating enclosure and provide the power to devices disposed within the EMI isolating enclosure (100) while providing EMI management services (e.g., electromagnetically isolating the devices disposed within the EMI isolated enclosure).

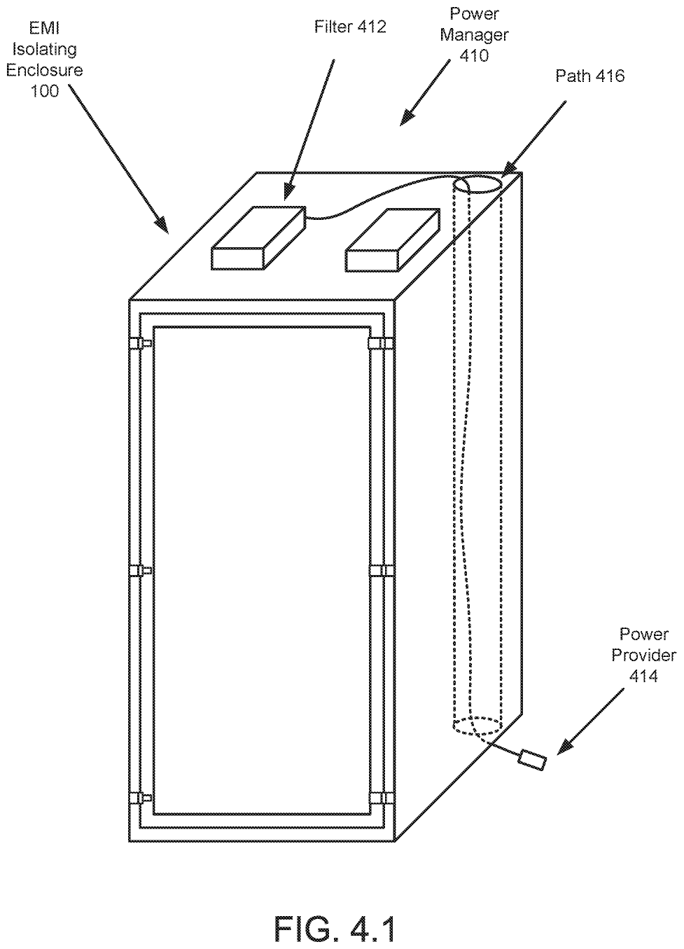

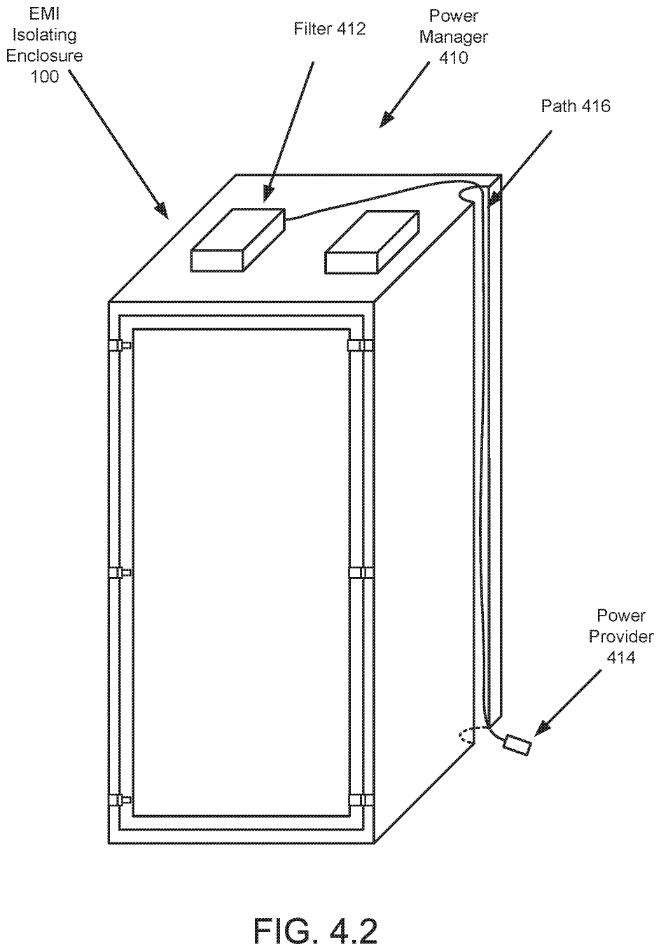

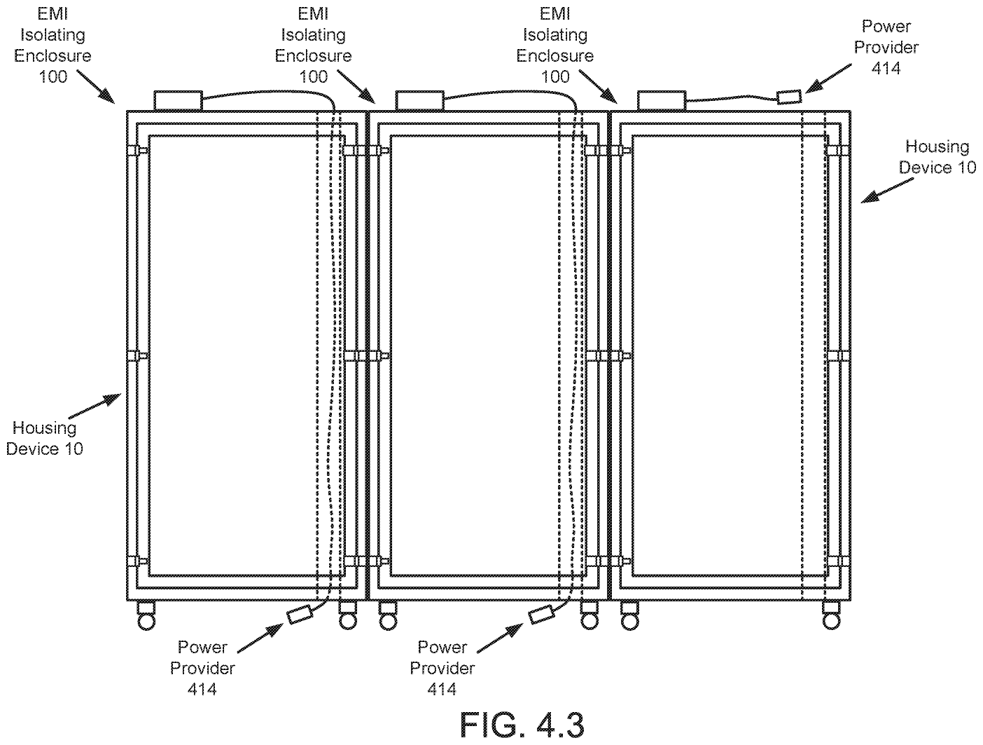

To provide power management services, the housing device (10) may include a power manager that obtained the power from an external source, takes steps necessary to transition the power through the EMI isolating enclosure, and/or distribute the power to devices disposed within the EMI isolating enclosure. For additional details regarding a power manager, refer to FIGS. 4.1-4.3.

To further discuss aspects of embodiments of the disclosed technology, each component of the system of FIG. 1.1 is discussed below.

The EMI isolating enclosure (100) may be a physical device. The EMI isolating enclosure (100) may include any number of portions that bound one or more interior volumes. The portions of the EMI isolating enclosure (100) may electromagnetically isolate the one or more interior volumes by at least 90 decibels or another suitable level of isolation from the other interior volumes and/or the ambient environment surrounding the EMI isolating enclosure (100).

The portions of the EMI isolating enclosure (100) may include, for example, a top (102), a side (104), a front (106), and a bottom (108). The portions may also include a rear (not shown) and a second side (not shown). The aforementioned portions may delineate an interior volume of the EMI isolating enclosure (100) from an ambient environment.

Each of the portions of the EMI isolating enclosure (100) may have a structure that prevents, limits, and/or attenuates electromagnetic radiation that attempts to propagate through the respective portions by at least 90 decibels. By doing so, the portions of the EMI isolating enclosure (100) may electromagnetically isolate the interior volume from an ambient environment (and/or other portion/volumes of the EMI isolating enclosure (100)).

To prevent, limit, and/or attenuate electromagnetic radiation, each of the portions may have a shape and/or be made of a material that is adapted to interact with electromagnetic radiation in a manner that limits the ability of electromagnetic radiation from propagating through the respective portions.

For example, a first portion (e.g., top (102)) of the EMI isolating enclosure (100) may include a planar sheet (or other shape) of high conductivity material (e.g., aluminum, copper, brass, steel, etc.). The planar sheet may have a thickness that, in combination with the high conductivity of the planar sheet, prevents electromagnetic radiation from propagating through the portion resulting in the electromagnetic radiation being reflected back into an interior volume (where it may be absorbed by one or more structures disposed within the interior volume).

In another example, a second portion (e.g., side (104)) of the EMI isolating enclosure (100) may include a planar sheet (or other shape) of lossy material (e.g., carbon loaded polymer, etc.). The planar sheet may have a thickness that, in combination with the lossy material of the planar sheet, absorbs electromagnetic radiation as it propagates through the portion resulting in the electromagnetic radiation being transformed into heat via absorption.

In a further example, a third portion (e.g., second side (not shown)) of the EMI isolating enclosure (100) may include a planar sheet (or other shape) of conductive and lossy material (e.g., metal particle and carbon particle loaded polymer, etc.). The planar sheet may have a thickness that, in combination with the conductive and lossy material of the planar sheet, absorbs and/or reflects electromagnetic radiation as it attempts to propagate through the portion resulting in some of the electromagnetic radiation being transformed into heat via absorption and the remainder being reflected into the interior volume.

In one or more embodiments of the invention, the portions of the EMI isolating enclosure (100) are non-structural. For example, the portions of the EMI isolating enclosure (100) may not be adapted to receive loads from devices or other components disposed within the EMI isolating enclosure (100), other portions of the EMI isolating enclosure (100), and/or other devices/structures disposed outside of the EMI isolating enclosure (100). Thus, the portions of the EMI isolating enclosure (100) may provide EMI isolation services without providing structure management services (e.g., receiving/transmitting loads/pressures).

In one or more embodiments of the invention, the portions of the EMI isolating enclosure (100) may be physically connected by unstressed joints (e.g., 109). An unstressed joint may be a physical component that is adapted to provide EMI isolation services but not structure management services. For example, the unstressed joints (109) may be formed of conductive material, such as metal, but may not be adapted to transmit force/stresses on the EMI isolating enclosure (100). Thus, the unstressed joints (e.g., 109) may be subject to failure if force/stresses are applied to the unstressed joints in a manner consistent with structure management services (e.g., transmitting loads/stresses/forces through the unstressed joint to maintain the structure of the EMI isolating enclosure (100) and/or other devices disposed within the :EMI isolating enclosure (100)).

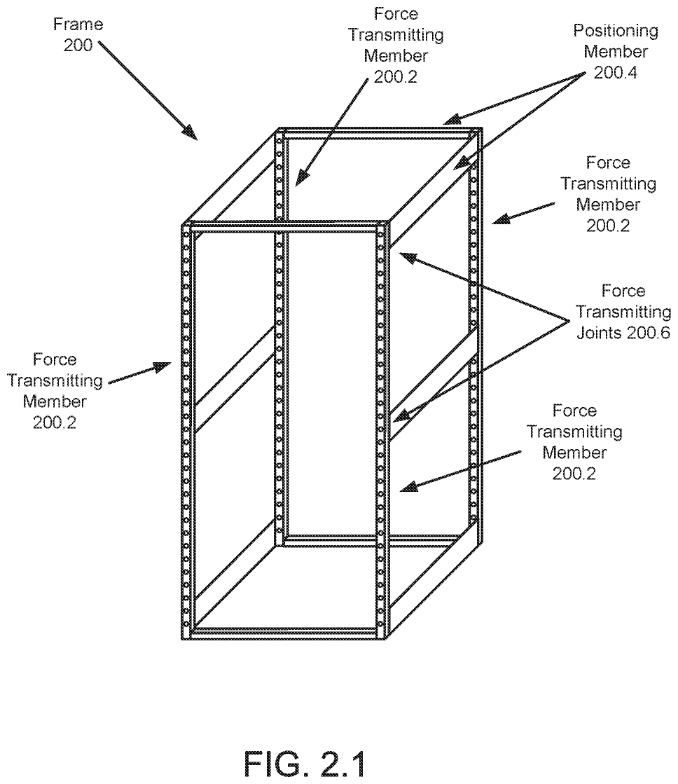

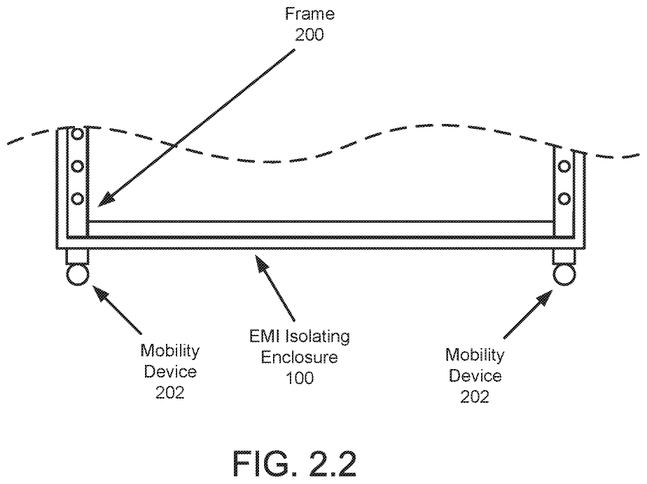

To maintain the structure of the EMI isolating enclosure (100), a frame may be disposed within the EMI isolating enclosure (100). The frame may be a structural component that provides structure management services to the EMI isolating enclosure (100) and/or other devices. For example, the portions of the EMI isolating enclosure (100) may be physically attached to the frame in a manner that preferentially causes loads/stresses/forces from the EMI isolating enclosure (100) to be transmitted to the frame rather than through the unstressed joints. By doing so, unstressed joints may be shielded from stresses that may damage/degrade the ability of the unstressed joints to provide EMI isolation services. For additional details regarding frames, refer to FIG. 2.1.

For example, stresses placed on the unstressed joints may lead to cracking or other changes in the physical structure of the EMI isolating enclosure (100) that enables electromagnetic radiation to propagate through the EMI isolating enclosure (100) without being attenuated. By transmitting forces applied to the portions of the EMI isolating enclosure (100) through the frame (rather than through the unstressed joints or other portions of the EMI isolating enclosure) the likelihood of changes in the structure of the unstressed joints resulting in propagation of EMI through the unstressed joints (e.g., 109) may be reduced.

The EMI isolating enclosure (100) may also include an access portion (107). The access portion (107) may enable an interior volume of the EMI isolating enclosure (100) to be accessed. For example, the access portion (107) may be a structure that enables the EMI isolating enclosure (100) to be sealed when the access portion (107) is in a first state and unsealed (e.g., open) when the access portion (107) is in a second state.

For example, the access portion (107) may be a door physically connected to the other portions of the EMI isolating enclosure (100) and/or other structures such as a frame via hinges (107.4) that enable the door to move between different states and latches (107.2) that enable the door to be reversibly fixed in a desired state (e.g., closed).

Additionally, the access portion (107) may enable the interior of the EMI isolating enclosure to be ventilated. For example, one or more portions of the access portion (107) may be gas permeable while still preventing/limiting the transmission of EMI through the access portion (107).

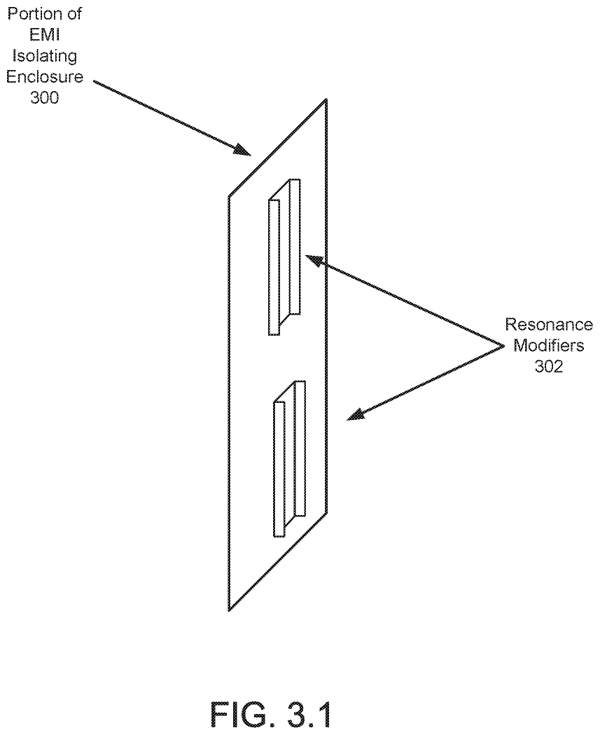

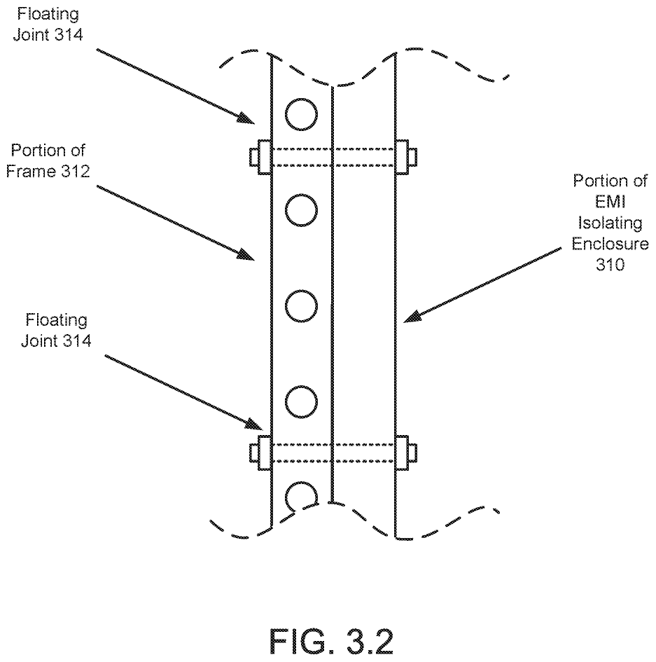

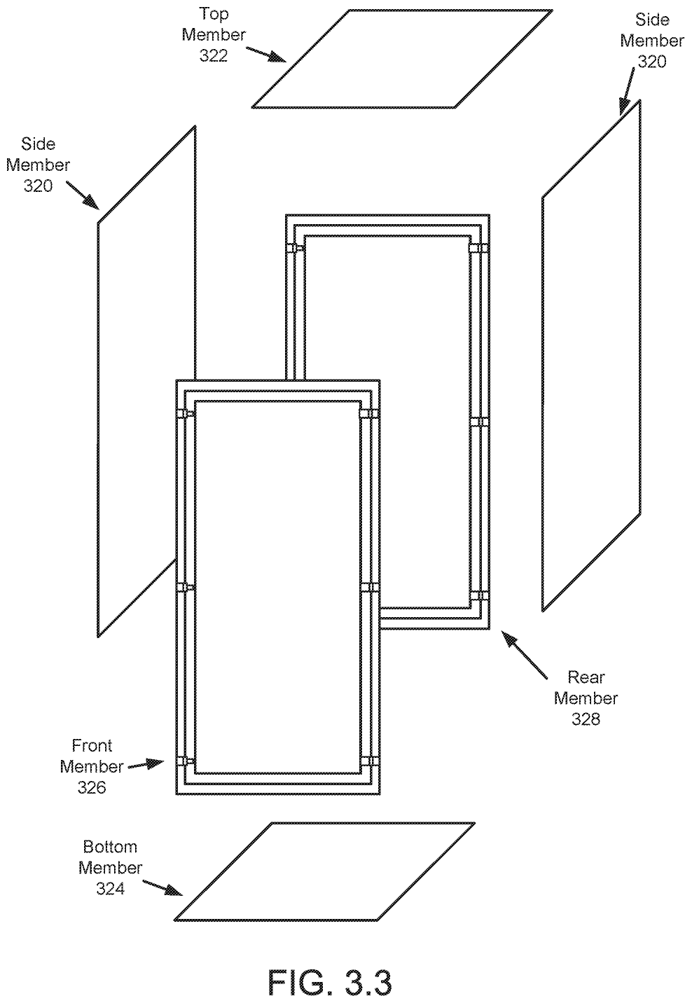

While only a single access portion (107) is illustrated in FIG. 1.1, an EMI isolating enclosure may include any number of access portions. For example, two access portions may be disposed on opposite portions (e.g., front (106) and a back/rear (not shown)) of the EMI isolating enclosure (100) to define a gas flow path through the interior of the EMI isolating enclosure. By doing so, the thermal state devices disposed within the EMI isolating enclosure (100) may be regulated through the flow of gasses through the gas flow path while preventing/limiting the transmission of EMI through the EMI isolating enclosure (100). For additional details regarding access portions, refer to FIG. 3.

While the system of FIG. 1.1 has been illustrated and described as including a limited number of specific components, a system in accordance with one or more embodiments of the invention may include additional, fewer, and/or different components without departing from the invention.

As discussed above, an EMI isolating enclosure (100) may provide electromagnetic interference management services for devices. To do so, the EMI isolating enclosure (100) may enable EMI emitting devices to be added to and/or removed from an interior volume bounded by the EMI isolating enclosure.

FIG. 1.2 shows a diagram of the system of FIG. 1.1 in a state in which devices may be added to or removed from an interior volume of the EMI isolating enclosure in accordance with one or more embodiments of the invention. Specifically, the access portion of the EMI isolating enclosure (100) has been moved from a first state in which the EMI isolating enclosure (100) is sealed to a second state in which the EMI isolating enclosure (100) is unsealed.

To enable EMI emitting devices to be disposed within the EMI isolating enclosure (100), one or more data processing devices (110) may be disposed within the EMI isolating enclosure (100), A data processing device may be a physical structure for housing EMI emitting devices, computing devices, and/or other types of devices.

For example, a data processing device may include a chassis. The chassis may be adapted to receive devices and to physically attach to one or more portions of the system of FIG. 1.2. For example, the chassis may be adapted to physically attach to a frame to which the EMI isolating enclosure (100) is attached. As discussed above, a frame may be a structural component that provides structure management services to other devices (e.g., the EMI isolating enclosure (100) and/or the data processing devices (110)).

The data processing devices (110) may be attached to the frame in any manner. For example, the data processing devices (110) may be attached to the frame by, for example, rails, pins, bolts, etc.

FIG. 1.3 shows a diagram of the system of FIG. 1.2 in a state in which one of the data processing devices (110) has been repositioned with respect to the EMI isolating enclosure (100) in accordance with one or more embodiments of the invention. For example, the repositioned data processing device (113) may have been repositioned using rails or another type of mechanism by which it is connected to the frame. By repositioning the data processing device, portions of the repositioned data processing device (113) that were inaccessible may be accessed.

FIG. 1.4 shows a diagram of the system of FIG. 1.3 in a state in which one of the portions of the repositioned data processing device (113) has accessed in accordance with one or more embodiments of the invention. For example, the repositioned data processing device (113) may have been accessed by removing/repositioning a cover or other physical structure that defines a boundary of the repositioned data processing device (113). By removing/repositioning a portion of the data processing device, EMI emitting devices (120) disposed within the repositioned data processing device (113) may be accessed. For example, EMI emitting devices (120) may be added to and/or removed from the repositioned data processing device (113).

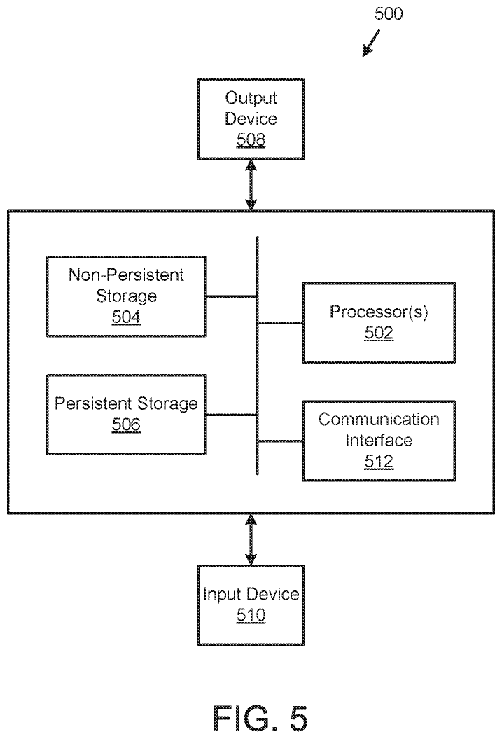

As discussed above, EMI emitting devices may be implemented using computing devices (and/or other types of devices that include computing devices may be disposed within the data processing devices (110)). For additional details regarding computing devices, refer to FIG. 5.

As discussed above, data processing devices may be attached to a frame, rather than an EMI isolating enclosure. By doing so, stresses/forces that may otherwise impact the ability of the EMI isolating enclosure to provide EMI isolation services may be mitigated by transmitting them through the frame rather than the EMI isolating enclosure. FIG. 2.1 shows a diagram of a frame (200) in accordance with one or more embodiments of the invention.

The frame (200) may be a physical structure that provides structure management services to the EMI isolating enclosure and/or other devices (e.g., data processing devices and/or other types of devices). For example, the frame (200) may receive stresses/forces from devices attached to the frame (200) and transmit the stresses/forces in a manner that does not impact other components.

For example, the frame (200) may transmit forces/stresses that it receives to a structure upon which the frame (200) is disposed. For additional details regarding transmission of stresses from the frame to other devices, refer to FIG. 2.2.

To provide structure management services, the frame (200) may include any number of structural members. The structural members may form a structure upon which other components (e.g., EMI isolating enclosure) may be mounted to position the aforementioned components with respect to one another. For example, the portions of the EMI isolating enclosure may be disposed on the outside of the structural members thereby providing EMI isolation services to other devices attached to the frame (200).

The frame (200) may include one or more force transmitting members (e.g., 200.2). The force transmitting members may be adapted to receive forces/stresses transmitted to the frame (200) by other devices and transmit the received forces/stresses to other devices such as a structure upon which the frame is disposed. The frame (200) may do so directly or indirectly by transmitting the received forces/stresses through other structures. Refer to FIG. 2.2 for additional details regarding transmission of forces to other structures.

The force transmitting members (e.g., 200.2) may be, for example, tubular structures. The tubular structures may have a cross section (e.g., square, rectangular) that stiffens the force transmitting members. The force transmitting members (e,g., 200.2) may be of other shapes (and/or different force transmitting members may be of different shapes) without departing from the invention.

The frame (200) may include one or more positioning members (e.g., 200.4). The one or more positioning members (e.g., 200.4) may be adapted to maintain the relative positioning and/or orientation of the force transmitting members with respect to each other. For example, the one or more positioning members (e.g., 200.4) may be, for example, tubular structures. The tubular structures may have a cross section (e.g., square, rectangular) that stiffens the one or more positioning members (e.g., 200.4). The one or more positioning members (e.g. 200.4) may be of other shapes (and/or different force transmitting members may be of different shapes) without departing from the invention.

The one or more positioning members (e.g., 200.4) may be physically attached to the force transmitting members and/or other structures via force transmitting joints (200.6). The force transmitting joints (200.6) may enable forces/stresses to be transmitted between the force transmitting members and/or the positioning members. By doing so, the force transmitting members and/or the positioning members may provide structure management services by enabling forces/stresses applied to the frame (200) to be managed with minimal change to the relative positioning/orienting of the force transmitting members and/or the positioning members with respect to each other.

The frame (200) may further include any number of attachment points (illustrated as circles in FIG. 2.1). The attachment points may enable other structures (e.g., chassis of data processing devices, EMI isolating enclosure portions, etc.) to be attached to the frame (200). The attachment points may be any type of structure that enables other structures to be attached to the frame (200) using the attachment points. For example, one or more of the attachment points may be a hole through one of the members of the frame (200). The hole may be used to attach other structures to the frame using bolts or other types of attachment components (e.g., screws, wedges, pins, etc.).

In one or more embodiments of the invention, the frame (200) has a rectangular shape. For example, the components (e.g., 200.2, 200.4) of the frame may be arranged in a manner that defines a volume having a rectangular cross section of a predetermined length.

In one or more embodiments of the invention, the frame (200) is structural. For example, the components of the frame (200) may be adapted to maintain their position and/or orientation with respect to each other. In one or more embodiments of the invention, the frame (200) is a high precision structure. For example, the relative positioning of the force transmitting members (e.g., 200.2) may be of high accuracy (e.g., within 0.5 mm of a predetermined positioning tolerance). In contrast, the portions of the EMI isolating enclosure may not be structural and may be a low precision. For example, the relative positioning of the portions of the EMI isolating enclosure with respect to each other may be of low accuracy (e.g., within 3 mm of a predetermined positioning tolerance).

By doing so, the frame (200) may provide the positioning tolerances necessary to enable high precision devices such as a chassis of data processing devices to be mounted to the frame (200) while enabling the EMI isolating enclosure to be manufactured in a manner that decreases the likelihood of EMI propagating out of the EMI isolating enclosure without being attenuated (e.g., through a defect in a joint or other structure). For example, low precision manufacturing methods such as welding or joining portions by bolts (but have a high likelihood of preventing EMI propagation through the joint) may be utilized to attach the portions of the EMI isolating enclosure to each other and/or to the frame (200).

While the frame (200) is illustrated in FIG. 2.1 as including four force transmitting members and 10 positioning members, a frame (200) in accordance with one or more embodiments of the invention may include fewer and/or additional numbers of the aforementioned components without departing from the invention. Further, a frame (200) in accordance with one or more embodiments of the invention may include fewer, additional, and/or different components than those illustrated in FIG. 2.1.

As discussed above, the frame (200) may enable forces to be transmitted to other structures such as a platform upon which a system including a frame (200) is disposed. FIG. 2.2 shows a diagram of a portion of a frame (200) in accordance with one or more embodiments of the invention.

As seen from FIG. 2.2, a system in accordance with embodiments of the invention may include one or more mobility devices (e.g., 202). The mobility devices (e.g., 202) may be devices that enable forces to be transmitted by the frame (200) to other structures. The mobility devices may include, for example, casters, wheels, feet, or other types of structures that may enable forces to be transmitted to other devices (e.g., a surface upon which a housing device is disposed).

The one or more mobility devices (202) may be separated from the frame (200) by a portion of the EMI isolating enclosure (100). The members of the frame (200) may be attached to the mobility devices (202) in a manner that prevents forces from the frame (200) to impact the structural integrity of the portion of the EMI isolating enclosure separating the mobility devices from the frame. For example, the members of the frame (200) may be stacked directly on top of the mobility devices which enables stresses/forces to be transmitted through the portion of the EMI isolating enclosure between the frame (200) and the mobility devices without tending to deform a shape of the portion of the EMI isolating enclosure.

In another example, the system may include adapters (not shown) that structurally reinforce the portion of the EMI isolating enclosure (100) through which forces from the frame (200) are transmitted to the mobility devices (e.g., 202). For example, plates that structurally reinforce portions of the EMI isolating enclosure (100) may be added. In such a scenario, the mobility devices (202) may not be stacked directly below the members of the frame (200). For example, the mobility devices may be offset from corresponding locations of members of the frame. The plates (or other physical structures) may enable forces to be transmitted to the offset mobility devices without negatively impacting the structure of the EMI isolating enclosure (200).

As discussed above, a system in accordance with embodiments of the invention may include an EMI isolating enclosure. FIGS. 3.1-3.3 show diagrams of an EMI isolating enclosure, or portions thereof, in accordance with one or more embodiments of the invention.

FIG. 3.1 shows a diagram of a portion of an EMI isolating enclosure (300) in accordance with one or more embodiments of the invention. The portion may correspond to any portion of the EMI isolating enclosure illustrated in FIG. 1.1. For additional details regarding the various portions of an EMI isolating enclosure, refer to FIG. 3.3.

As discussed above, the portions of the EMI isolating enclosure may include sheets of material that delineate boundaries of an internal volume of the EMI isolating enclosure. The sheets of material may be adapted to (i) prevent/attenuate propagating EMI as it propagates out of the interior volume, (ii) limit the forces applied to the frame (e.g., 200, FIG. 2.1) by being of a thickness/material capable of providing EMI isolation but not able to provide structure management, and/or (iii) be transported.

To be adapted for transportation, the portion of the EMI isolating enclosure (300) may include one or more resonance modifiers (302). A resonance modifier may be a structure adapted to modify a mechanical resonance of another structure. For example, when structures are excited via mechanical (e.g., acoustical) forces, the structures may resonate which may greatly increase the stresses/forces applied to the structures. The resonance modifiers (302) may be adapted to modify a resonance of the portion of the EMI isolating enclosure (300) outside of a frequency band in which a system may be subject to mechanical forces during transportation. The frequency band may be, for example, from 10-120 Hertz. The resonance modifiers (302) may modify a natural resonance of one of the components (e.g., a sheet of material) of the portion of the EMI isolating enclosure (300) to be outside of the frequency band associated with transportation.

The resonance modifiers (302) may be, for example, physical structures that have a natural resonance outside of the frequency band associated with transportation. The physical structures may be, for example, portions of C channel, tubular members, or other physical structures that have a natural resonance substantially outside of the frequency band associated with transportation. When the resonance modifiers (302) are attached to the portion of the EMI isolating enclosure (300), the natural mechanical resonances of the combined structure may be outside of the frequency band associated with transportation.

Any portion of the EMI isolating enclosure may include any number and/or type of resonance modifiers. Different portions may include resonance modifiers with different characteristics (e.g., size, thickness, material, etc.).

In one or more embodiments of the invention, the resonance modifiers (302) may be compliant members. The compliant members may absorb or otherwise prevent mechanical vibrations to be transmitted to a portion of the EMI isolating enclosure, or another portion of the housing device. For example, the resonance modifiers (302) may be dampers disposed between the frame and a portion of the EMI isolating enclosure (300).

The resonance modifiers (302), by preventing the portion of the EMI isolating enclosure from resonating, may decrease the forces applied to other portions of the housing device due to resonance. For example, forces on the unstressed joints due to resonances of the portions of the EMI isolating enclosure (or other portions of the housing device) may be reduced and/or eliminated.

As discussed above, the portions of the EMI isolating enclosure may be non-structural in that the portions are not adapted to bear stresses/forces from other structures. To arrange the portions of the EMI isolating enclosure with respect to each other, the portions of the EMI isolating enclosure may be physically attached to the frame. FIG. 3.2 shows a diagram of an attachment between a portion of the EMI isolating enclosure (310) and a portion of the frame (312).

The attachments between the portion of the frame (312) and the portion of the EMI isolating enclosure (310) may be made using one or more floating joints (e.g., 414). A floating joint may be a type of physical connection that enables a low accuracy structure to be attached to a high accuracy structure while enabling forces/stresses to be transmitted via the physical connections. By being connected via floating joints, the frame may be able to meet the high precision tolerances of devices to be disposed in the frame while also allowing the EMI isolating enclosure to be attached to the frame without negatively impacting the accuracy provided by the frame.

For example, a floating joint (314) may be a physical joint between two structures that assumes there will be some mismatch in the positioning of features on the two structures that enables the physical joint to be made. For example, as illustrated in FIG. 3.2, multiple joints may be employed to position/orient portions of an EMI isolating enclosure. However, because of the low accuracy nature of the EMI isolating enclosure, holes that enable the EMI isolating enclosure to be attached to the frame by using, for example, bolts (or other types of interconnection devices such as screws, wedges, etc.), may be spaced further apart or closer together than corresponding holes on the frame. To address this potential issue, the holes on the portion of the frame (312) and/or the portion of the EMI isolating enclosure (310) may be oversized, have an oval shape, or may otherwise include a mechanism for taking into account the mismatch in the positioning of the holes (or other types of structures for enabling two structures to be physically connected). By doing so, stresses/forces applied to the frame by the portion of the EMI isolating enclosure (310) due to the physical attachment may be reduced, mitigated, or otherwise minimized.

As noted above, the EMI isolating enclosure may be formed of multiple members, FIG. 3.3 shows a diagram of members of an EMI isolating enclosure in accordance with one or more embodiments of the invention.

An EMI isolating enclosure may include, for example, six members that define the boundary of a rectangular volume. The six members may be, for example, a top member (322), a bottom member (324), two side members (e.g., 320), a front member (326), and a rear member (328).

To form the EMI isolating enclosure, the members of the EMI isolating enclosure may be electrically connected to each other via unstressed joints, as illustrated in FIG. 1.1. When connected to each other, at least two of the members (e.g., front member (326) and rear member (328)) may include access portions. The included access portions may define a gas flow path through an interior of the EMI isolating enclosure. By including a continuous vent in at least one of the access portions, showing effects on the flow of gas through the interior volume may be greatly reduced when compared to access portions that include multiple, discrete vents.

For example, access portions that include multiple, discrete vents may generate turbulent flows of gas and/or may cause shadow regions inside the interior volume to form. The shadow regions may have greatly reduced gas flow rates when compared to other regions that are not shadowed. Such shadow regions may prevent or otherwise limit the ability of components disposed within the interior volume to be cooled via the flow of gas through the interior volume. Consequently, inclusion of at least one continuous vent may improve the ability of the system to provide thermal management services (e.g., cooling via gas flow) to components disposed within the internal volume while the components are EMI isolated by the EMI management services provided by the system.

As discussed with respect to FIG. 1.1, a housing device may include a power manager that provides power management services. FIG. 4.1 shows a diagram of a power manager (410) in accordance with one or more embodiments of the invention. To provide power management services, the power manager (410) may obtain power from sources that are external to the EMI isolating enclosure (100), transition the power through the EMI isolating enclosure to an interior of the EMI isolating enclosure while devices disposed within the EMI isolating enclosure are EMI isolated, and distribute the transitioned power to devices within the EMI enclosure.

To provide the above noted functionality, the power manager (410) may include a filter (412), a power provider (414), and a path (416). Each of these components are discussed below.

The filter (412) may be a physical device for filtering the power obtained from other sources. More specifically, the filter (412) may electromagnetically filter electromagnetic radiation as it attempts to traverse a pass through that separates an interior of the EMI isolating enclosure (100) from an ambient environment. By filtering electromagnetic radiation that attempts to traverse the pass through, the filter (412) may prevent and/or attenuate EMI as it escapes out of the EMI isolating enclosure (100) through the pass through.

For example, the filter (412) may be a low pass filter that enables electromagnetic radiation having a frequency content that is associated with power transmission to traverse the pass through without attenuation while severely attenuating electromagnetic radiation having a frequency content that is associated with EMI emitting devices disposed within the EMI isolating enclosure. The frequency content of the electromagnetic radiation associated with the EMI emitting devices may be greater than 100 MHz, greater than 1 MHz, etc.

The low pass filter may be adapted to attenuate electromagnetic radiation having a frequency content associated with the EMI emitting devices by at least 90 decibels or another suitable level of attenuation (as discussed with respect to FIG. 1.1). The low pass filter may further be adapted to not and/or minimally attenuate electromagnetic radiation having frequency content that is associated with power transmission. The frequency content of the electromagnetic radiation associated with power transmission may be less than 1 KHz, less than 1 MHz, less than 10 MHz, less than 100 MHz, etc. Thus, the filter (412) may enable electromagnetic radiation associated with power transmission to pass through the pass through without attenuation while attenuating electromagnetic radiation associated with the emitting devices. By doing so, the devices disposed within the EMI isolating enclosure (100) may be electromagnetic isolated while receiving power from sources outside of the EMI isolating enclosure.

In one or more embodiments of the invention, the filter (412) is fixedly attached to a power of the EMI isolating enclosure, in other words, the filter (412) may not be adapted to be moved from a particular location on the EMI isolating enclosure (100). For example, to appropriately filter electromagnetic radiation, the filter (412) may include a housing that electrically isolates the components of the filter (412) that provides filtering functionality from an ambient environment. To provide such isolation, the housing of the filter may need to make a continuous electromagnetic seal to the portion of the EMI isolating enclosure (100) upon which the housing is disposed. Making such seals may be extremely challenging and/or require validation using expensive testing equipment. Thus, once attached to the EMI isolating enclosure (100) the filter (412) may not be adapted to be moved from is location of disposition.

In addition to the filter, the power manager (410) may include additional components for obtaining and distribution of power. Like the filter, any of the additional components may be adapted to be fixedly attached to the EMI isolating enclosure.

The power manager (410) may also include a power provider (414). The power provider (414) may be a physical device for obtaining power from a source. For example, the power provider (414) may be a plug and a length of wire adapted to transmit power to the filter (412) or other components of the power manager (410) fixedly attached to the EMI isolating enclosure (100).

In one or more embodiments of the invention, the power provider (414) includes a length of wire adapted to enable the power provider (414) to obtain power from sources disposed above or below the system. For example, in a high density computing environment, systems similar to that illustrated in FIG. 4.1 may receive power from above, or below. In other words, electrical sources may be disposed above and/or below the system.

To enable power to be obtained from above and/or below the system, the length of wire may have a sufficient length and gauge to enable the power provider (414) to physically connect to sources of power above or below the system. The gauge of the wire may be adapted to meet requirements of a predetermined load which the devices disposed within the EMI isolating enclosure are likely to draw.

However, in a high density environment (or similar environment, e.g., HPC environment, data center, super computing center, etc.), the locations of systems such as that illustrated in FIG. 4.1 may be selected for density reasons. Thus, it may be impractical and/or impossible to string a length of wire around one of the sides of the system.

To address this and/or other potential space related issues, the EMI isolating enclosure (100) may include a path (416). The path (416) may traverse through the interior volume of the EMI isolating enclosure (100) and may be electromagnetically isolated from the interior volume. For example, a tubular member may extend from a first portion of the EMI isolating enclosure (100), through the interior volume of the EMI isolating enclosure (100), and to a second portion of the EMI isolating enclosure (100). An example of such a path (e.g., 416) is illustrated in FIG. 4.1 using short dashing to show hidden portions of the path (416) and portions of the power provider (414) illustrated as traversing the path (416).

The tubular member may be conductive and may be electrically attached to the first portion and the second portion. By doing so, the interior volume of the path (416) may be electromagnetically isolated from an interior volume of the EMI isolating enclosure (100). Thus, portions of the power provider (414) may reversibly traverse the path (416) to enable the plug of the power provider (414) to physically interface with a power source to provide power to the filter (412) and/or other portions of the power manager (410).

While the path (416) is illustrated in FIG. 4.1 as being a tube, the path (416) may have other shapes and/or be located in other locations and/or may interconnect different portions of the EMI isolating enclosure without departing from the invention. For example, the path (416) may interconnect the top with a side. In another example, the path (416) may have a square cross section. In a still further example, the path (416) may have a different shape as illustrated in FIG. 4.2.

Additionally, a power manager in accordance with embodiments of the invention may include additional components from those discussed here. For example, a power manager may include at least two power providers, each being adapted to obtain power from above or below a housing device. For example, the power provider adapted to obtain power from below the housing device may be fixedly routed through the path while the power provider adapted to obtain power from above the housing device may be fixedly attached to a top of the housing device. Both of these power providers may be attached to a switch (e.g., electromechanical relays) that enables power to be provided from only one of the power providers at a time. In turn, the switch may provide the power to the power filter. By doing so, a power provider may not need to be repositioned depending upon the location of available power sources.

Further, while embodiments of the invention have been described with respect use of a path that traverses through a portion of the EMI isolating enclosure, a power provider in accordance with embodiments of the invention may traverse other paths that do not traverse through the EMI isolating enclosure. For example, a portion of the power provider (e.g., insulated wires) may traverse along an exterior surface of the EMI isolating enclosure without departing from the invention.

FIG. 4.2 shows a second diagram of a power manager (410) in accordance with one or more embodiments of the invention. In FIG. 4.2, the power manager (410) includes a path (416) disposed along a boundary of the EMI isolating enclosure (100). The path (416) may have other shapes, may be located in other locations, and/or may have different characteristics without departing from the invention.

To further clarify aspect of paths with respect to power managers, FIG. 4.3 shows a diagram of multiple housing devices (e.g., 10) in accordance with one or more embodiments of the invention. In FIG. 4.3, the housing devices are illustrated in a configuration that may be common in a high density computing environment.

Specifically, the housing devices may be packed tightly together making it impractical to have portions of the power providers run outside of the EMI isolating enclosures.

For example, consider a scenario where the housing devices on the left and in the center only have access to power sources disposed below the housing devices while the housing devices on the right has access to a power source disposed above the housing device. In such a scenario, the power providers (414) of the housing devices on the left and center of the figure may traverse through the paths (shown in short dashing) through the interior volumes of the housing devices. In contrast, the power provider (414) of the housing device on the right of the figure may not need to traverse through the path to obtain power.

Thus, as illustrated in FIG. 4.3, a housing device in accordance with one or more embodiments of the invention may be reconfigurable to obtain power from below, above, or from other locations (e.g., near a side of a housing device). By doing so, a housing device in accordance with embodiments of the invention may provide a better ability to be integrated with other types of equipment found in high density computing environments.

For example, the count of such housing devices within a predetermined amount of space may be able to be increased by stacking them more closely together when power providers traverse through the EMI isolating enclosure rather than around the EMI isolating enclosure. With respect to FIG. 4.3, had paths through the EMI isolating enclosures not been available, space between the housing devices or in front/behind for power provider routing purposes may have inherently decrease the maximum possible density of such housing devices.

As discussed above, embodiments of the invention may be implemented using computing devices. FIG. 5 shows a diagram of a computing device in accordance with one or more embodiments of the invention. The computing device (500) may include one or more computer processors (502), non-persistent storage (504) (e.g., volatile memory, such as random access memory (RAM), cache memory), persistent storage (506) (e.g., a hard disk, an optical drive such as a compact disk (CD) drive or digital versatile disk (DVD) drive, a flash memory, etc.), a communication interface (512) (e.g., Bluetooth interface, infrared interface, network interface, optical interface, etc.), input devices (510), output devices (508), and numerous other elements (not shown) and functionalities. Each of these components is described below.

In one embodiment of the invention, the computer processor(s) (502) may be an integrated circuit for processing instructions. For example, the computer processor(s) may be one or more cores or micro-cores of a processor. The computing device (500) may also include one or more input devices (510), such as a touchscreen, keyboard, mouse, microphone, touchpad, electronic pen, or any other type of input device. Further, the communication interface (512) may include an integrated circuit for connecting the computing device (500) to a network (not shown) (e.g., a local area network (LAN), a wide area network (WAN) such as the Internet, mobile network, or any other type of network) and/or to another device, such as another computing device.

In one embodiment of the invention, the computing device (500) may include one or more output devices (508), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (502), non-persistent storage (504), and persistent storage (506), Many different types of computing devices exist, and the aforementioned input and output device(s) may take other forms.

Embodiments of the invention may provide methods, devices, and/or systems for managing power for EMI isolated devices. Specifically, embodiments of the invention may provide a power manager that is able to provide power from external sources while the devices are EMI isolated. Additionally, the power manager may be adapted to be reversibly reconfigured to obtain power from different locations and/or in a tight quarters environment where space is at a premium. To do so, the power manager may utilize a path through an interior of an EMI isolated enclosure that is, itself, electromagnetically isolated from the interior volume of the EMI isolated enclosure. By doing so, the power manager may be able to be reconfigured without moving/relocating other components of the power manager.

The problems discussed above should be understood as being examples of problems solved by embodiments of the invention disclosed herein and the invention should not be limited to solving the same/similar problems. The disclosed invention is broadly applicable to address a range of problems beyond those discussed herein.

One or more embodiments of the invention may be implemented using instructions executed by one or more processors of the data management device. Further, such instructions may correspond to computer readable instructions that are stored on one or more non-transitory computer readable mediums.

While the invention has been described above with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A housing device for isolating electromagnetic interference emitting (EMI) devices, comprising:
an EMI isolating enclosure; and
a power manager comprising:
a filter mounted to a first portion of the EMI isolating enclosure;
a path, through the EMI isolating enclosure, that is isolated from an interior of the EMI isolating enclosure; and
a power provider adapted to provide power to the filter by obtaining the power using the path.

2. The housing device of claim 1, wherein the path is connected to the first portion of the EMI isolating enclosure and a second portion of the EMI isolating enclosure.

3. The housing device of claim 2, further comprising a mobility device disposed on the second portion.

4. The housing device of claim 2, wherein the first portion is a top of the EMI isolating enclosure and the second portion is a bottom of the EMI isolating enclosure.

5. The housing device of claim 2, wherein the path comprises:
a first aperture through the first portion into a portion of the interior of the EMI isolating enclosure;
a tube that electromagnetically isolates the portion of the interior from a remaining portion of the interior of the EMI isolating enclosure; and
a second aperture through the second portion into the portion of the interior of the EMI isolating enclosure.

6. The housing device of claim 1, wherein the filter is adapted to be permanently attached to the first portion of the EMI isolating enclosure.

7. The housing device of claim 1, wherein the power provider is further adapted to provide power to the filter by obtaining the power without using the path.

8. The housing device of claim 1, wherein the power provider provides power to the filter by obtaining the power from a source proximate to the first portion of the EMI isolating enclosure.

9. The housing device of claim 1, wherein the power provider provides power to the filter by obtaining the power from a source proximate to a second portion of the EMI isolating enclosure.

10. The housing device of claim 9, wherein the second portion of the EMI isolating enclosure is connected to the first portion of the EMI isolating enclosure via the path.

11. The housing device of claim 1, wherein the filter is a low pass filter.

12. The housing device of claim 11, wherein the low pass filter is adapted to suppress a flow of EMI generated by the EMI emitting devices through the filter.

13. The housing device of claim 12, wherein the low pass filter suppresses the flow by at least 90 decibels.

14. The housing device of claim 1, wherein the filter is adapted to isolate EMI generated by the EMI emitting devices from an ambient environment by at least 90 decibels.

15. The housing device of claim 1, wherein the EMI isolating enclosure is adapted to isolate the interior of the EMI isolating enclosure for an ambient environment.

16. The housing device of claim 15, wherein the isolation provided by the EMI isolating enclosure is at least 90 decibels.

17. The housing device of claim 1, wherein the filter is adapted to provide a portion of the power to at least one of the EMI emitting devices.

18. The housing device of claim 17, wherein the filter is adapted to provide the portion of the power to the at least one of the EMI emitting devices using a power supply disposed within the interior of the EMI isolating enclosure.

19. The housing device of claim 1, further comprising:
a frame, disposed within the EMI isolating enclosure, adapted to house the EMI emitting devices.

20. The housing device of claim 19, wherein the frame is adapted to structurally support the EMI isolating enclosure, wherein the EMI isolating enclosure is non-structural.
